(19) United States
(12) Patent Application Publication
(10) Pub. No.: US 2021/0367201 A1
(43) Pub. Date: Nov. 25, 2021

(54) THIN FILM PACKAGING STRUCTURE, THIN FILM PACKAGING METHOD AND DISPLAY PANEL

(71) Applicant: Yungu (Gu'an) Technology Co., Ltd., Langfang (CN)

(72) Inventors: Yaoyan WU, Langfeng (CN); Yawei LIU, Langfang (CN); Jinqiang LIU, Langfang (CN); Jiamei DU, Langfang (CN); Dongkun LIU, Langfang (CN)

(21) Appl. No.: 16/342,994

(22) PCT Filed: Nov. 19, 2018
(86) PCT No.: PCT/CN2018/116272

§ 371 Date: Apr. 18, 2019

(30) Foreign Application Priority Data
Apr. 25, 2018 (CN) 201810379438.3

(51) Int. Cl. H01L 51/52; H01L 51/56

(52) U.S. Cl. CPC H01L 51/5253; H01L 51/56

(57) ABSTRACT

Disclosed is a thin film packaging structure, a thin film packaging method, and a display panel. The thin film packaging structure (100) includes at least two laminated inorganic packaging layers (110, 130), an organic packaging layer (120) and an enhancing sealing structure (140). The organic packaging layer is disposed between two adjacent inorganic packaging layers (110, 130). The enhancing sealing structure (140) is disposed surrounding the organic packaging layer (120).

### CROSS-REFERENCE TO RELATED APPLICATIONS

The present application claims priority of Chinese Patent Application No. 201810379438.3, filed with the CNIPA on Apr. 25, 2018, and entitled “THIN FILM PACKAGING STRUCTURE, THIN FILM PACKAGING METHOD AND DISPLAY PANEL”, and the entire content of which is incorporated herein in its entirety.

### TECHNICAL FIELD

The present disclosure relates to the field of display technologies, more particularly to a thin film packaging structure, a thin film packaging method, and a display panel therewith.

### BACKGROUND

At present, since a thin film packaging structure of an OLED (Organic Light-Emitting Diode) device has an inorganic packaging layer that is thin and has a high stress, it is easy for cracks to occur around the inorganic packaging layer in the thin film packaging structure, and moisture and oxygen easily erode an interior of the OLED through the cracks, resulting in damages to the OLED device. Therefore, it is hard to improve packaging reliability of present thin film packaging structures.

### SUMMARY

According to various embodiments of the present application, a thin film packaging structure, a thin film packaging method and a display panel therewith are provided.

Provided is a thin film packaging structure, including:

at least two laminated inorganic packaging layers;

an organic packaging layer, disposed between two adjacent inorganic packaging layers; and

an enhancing sealing structure, disposed surrounding the organic packaging layer.

Provided is a thin film packaging method, including:

forming a first inorganic packaging layer;

forming an organic packaging layer overlaying the first inorganic packaging layer;

forming a second inorganic packaging layer overlaying the organic packaging layer;

forming an enhancing sealing structure surrounding the organic packaging layer.

Provided is a display panel, including a thin film packaging structure, wherein the thin film packaging structure thereof includes:

at least two laminated inorganic packaging layers;

an organic packaging layer, disposed between two adjacent inorganic packaging layers; and

an enhancing sealing structure, disposed surrounding the organic packaging layer.

Details of one or more embodiments of the present disclosure are set forth in the accompanying drawings and description below. Other features, objects, and advantages of the disclosure will be apparent from the description, the accompanying drawings, and the appended claims.

### BRIEF DESCRIPTION OF THE DRAWINGS

FIG. 1 is a cross-sectional view of a thin film packaging structure according to an embodiment.

FIG. 2 is a cross-sectional view of the thin film packaging structure according to another embodiment.

FIG. 3 is a flowchart of a thin film packaging method according to an embodiment.

FIG. 4 is a flowchart of a thin film packaging method according to another embodiment.

FIG. 5 is a flowchart of a thin film packaging method according to yet another embodiment.

### DETAILED DESCRIPTION OF THE EMBODIMENTS

In order to make the objects, technical solutions, and advantages of the present disclosure more comprehensible, the present disclosure is further set forth in detail below with reference to the accompanying drawings and embodiments. It should be understood that the detailed embodiments described herein are merely to explain the present disclosure, but not intended to limit the same.

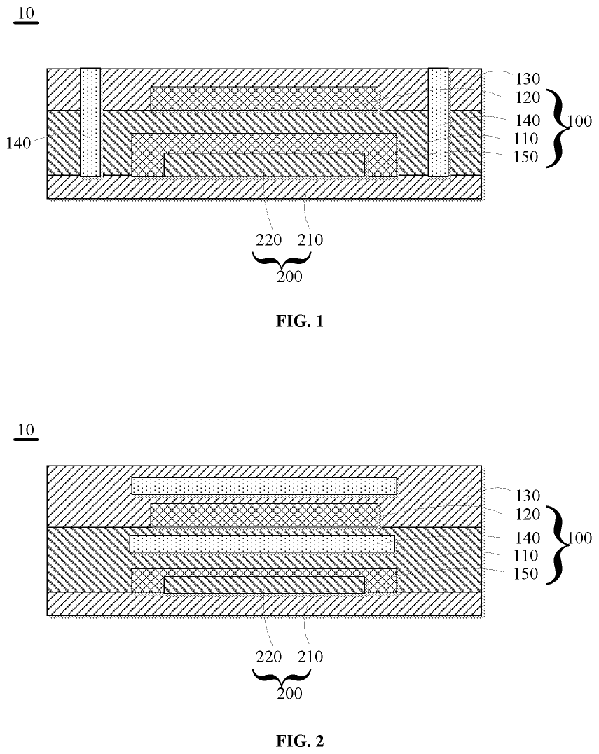

Referring to FIG. 1, a thin film packaging structure 100 according to an embodiment includes at least two laminated inorganic packaging layers, an organic packaging layer 120, and an enhancing sealing structure 140. The organic packaging layer 120 is disposed between two adjacent inorganic packaging layers. The enhancing sealing structure 140 is disposed surrounding the organic packaging layer 120.

Specifically, the two inorganic packaging layers adjacent to the organic packaging layer 120 are a first inorganic packaging layer 110 and a second inorganic packaging layer 130 respectively.

With the thin film packaging structure 100, an entire packaging strength is improved by providing the enhancing sealing structure 140. Moreover, the enhancing sealing structure 140 is disposed surrounding the organic packaging layer 120, avoiding the problem that the inorganic packaging layer is easily eroded by moisture and oxygen caused by being damaged. The enhancing sealing structure 140 is introduced innovatively into the thin film packaging structure 100 in an original packaging structure, improving packaging reliability.

In one of the embodiments, the enhancing sealing structure 140 is disposed surrounding a peripheral of the organic packaging layer 120 in a circumferential direction thereof. When a slight crack occurs in the inorganic packaging layer, the enhancing sealing structure 140 can prevent the crack from continuing to extend toward the centrally located organic packaging layer 120. This not only reduces generation of the crack in the inorganic packaging layer and prevents the crack from extending, thereby enhancing the strength of the inorganic packaging layer, but also effectively ensures the packaging reliability of the organic packaging layer 120.

Specifically, the enhancing sealing structure 140 is disposed in the inorganic packaging layer. Further, the enhancing sealing structure 140 is disposed in the inorganic packaging layer and proximate to an outer edge of the inorganic packaging layer. Such an arrangement not only avoids a contact of the enhancing sealing structure 140 with the organic packaging layer 120, but also reduces the packaging frame, and enlarges the display region.

In this embodiment, the first inorganic packaging layer 110 can be overlaid on an OLED layer 220 of an OLED device 200 to be packaged.

Further, the second inorganic packaging layer 130 and the first inorganic packaging layer 100 collectively clad the organic packaging layer 120. The first inorganic packaging layer 110 and the second inorganic packaging layer 130 contact to each other at an outer edge. The enhancing sealing structure 140 is disposed at the mutually contacted outer edge and penetrates at least one of the first inorganic packaging layer 110 and the second inorganic packaging layer 130. In such a way, the addition of the enhancing sealing structure 140 on the basis that the inorganic packaging layers clad the organic packaging layer 120 improves the packaging reliability of the organic packaging layer considerably.

In this embodiment, the second inorganic packaging layer 130 is further overlaid on the organic packaging layer 120, and cooperates with the first inorganic packaging layer 110 to collectively clad the organic packaging layer 120. The enhancing sealing structure 140 penetrates at least the second inorganic packaging layer 130. In this embodiment, the enhancing sealing structure 140 penetrates the first inorganic packaging layer 110 and the second inorganic packaging layer 130 at the same time.

It can be understood that disposing the enhancing sealing structure 140 in the inorganic packaging layer can be formed by the following method: providing a groove or a through hole surrounding the organic packaging layer 120 at a corresponding position in the inorganic packaging layer, and disposing the enhancing sealing structure 140 in the groove or the through hole.

Further, the enhancing sealing structure 140 is disposed in the groove or the through hole, and a surface of the enhancing sealing structure 140 is flush with a surface of the inorganic packaging layer in which the groove or the through hole is located.

In other embodiments, the enhancing sealing structure 140 can also be disposed directly surrounding the outer edge of the inorganic packaging layer, rather than in the inorganic packaging layer. In such a way, the enhancing sealing structure 140 being directly disposed surrounding the outer edge of the inorganic packaging layer can avoid the inorganic packaging layer to be impacted by stress, thus mitigating packaging failure of the thin film packaging structure 100, thereby improving the packaging reliability. It can be understood that in this case, since the enhancing sealing structure 140 is disposed surrounding the outer edge of the inorganic packaging layer directly, whereby the organic packaging layer 120 is cladded with the enhancing sealing structure 140 and the inorganic packaging layer collectively, the first inorganic packaging layer 110, the organic packaging layer 120 and the second inorganic packaging layer 130 can be laminated without cladding the organic packaging layer 120 with the second inorganic packaging layer 130 and the first inorganic packaging layer 110 collectively.

Further, the enhancing sealing structure 140 has a thickness greater than a thickness of the organic packaging layer 120. In such a way, on the basis that the enhancing sealing structure 140 is disposed surrounding the organic packaging layer 120, difficulty that moisture and oxygen erode the organic packaging layer 120 is increased, further improving the packaging reliability.

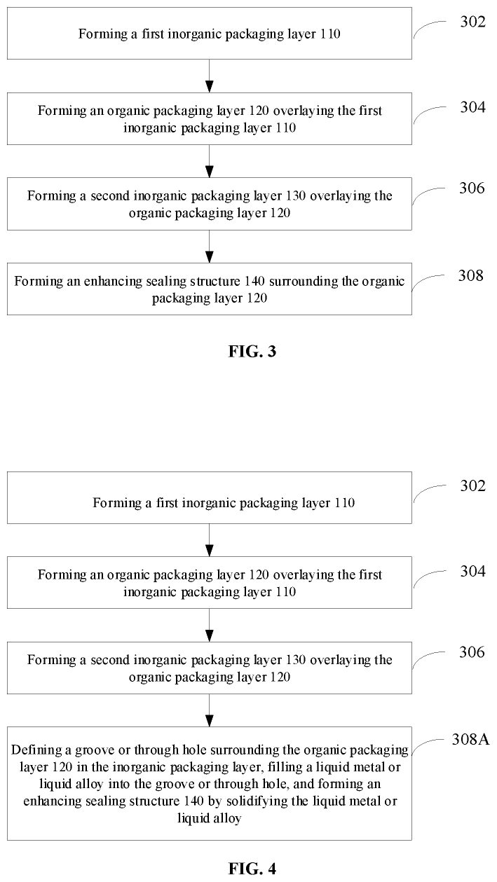

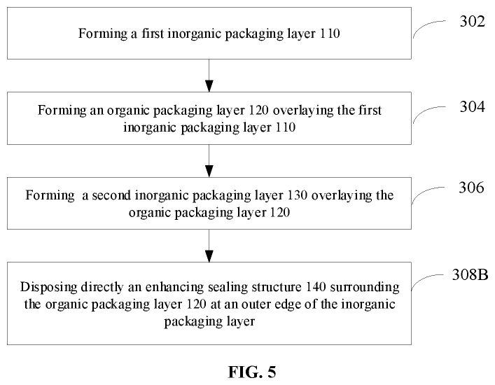

Referring to FIG. 2, a difference of the thin film packaging structure 100 according to another embodiment refers to a position of the enhancing sealing structure 140. The enhancing sealing structure 140 is located above and/or under the organic packaging layer 120. Further, the enhancing sealing structure 140 is disposed surrounding upper and lower surfaces of the organic packaging layer 120. The upper and lower surfaces are the two surfaces respectively adjacent to the first inorganic packaging layer 110 and the second inorganic packaging layer 130. Further, the enhancing sealing structure 140 can be disposed in the inorganic packaging layer. Specifically, a portion of the enhancing sealing structure 140 is disposed in the first inorganic packaging layer 110, and the other portion thereof is disposed in the second inorganic packaging layer 130. In an embodiment, the enhancing sealing structure 140 has a width greater than a width of the organic packaging layer 120. The width refers to a dimension along a length direction of the substrate 210.

Specifically, the enhancing sealing structure 140 is disposed surrounding the upper surface and the lower surface of the organic packaging layer 120 and at least part of a periphery thereof. In this embodiment, the enhancing sealing structure 140 is disposed surrounding the upper surface and the lower surface of the organic packaging layer 120 and a portion of the periphery connecting the upper and lower surfaces. In other embodiments, the enhancing sealing structure 140 can be disposed surrounding the upper surface and lower surface of the organic packaging layer 120 and the entire periphery connecting the upper and lower surfaces. In other words, the enhancing sealing structure 140 can be disposed surrounding a peripheral and the upper and lower surfaces of the organic packaging layer 120 at the same time.

Further, the enhancing sealing structure 140 is arranged evenly surrounding the organic packaging layer 120, whereby all the forces on the enhancing sealing structure 140 are even, thus avoiding a problem that the inorganic packaging layer is easily damaged due to stress concentration at individual positions where the enhancing sealing structure 140 is arranged unevenly, thereby improving the packaging reliability.

In one of the embodiments, a material of the enhancing sealing structure 140 is an alloy or a metal. In an embodiment, the material of the enhancing sealing structure 140 is one of metals of bismuth, lead, tin and cadmium, or an alloy formed by at least two of bismuth, lead, tin and cadmium.

In an embodiment, the metal is an alloy formed by at least two of bismuth, lead, tin and cadmium. This kind of alloys has properties of relatively low melting point and great optical transmission.

Further, the material of the enhancing sealing structure 140 is an alloy having a melting point of 80° C. to 100° C. Alloys having a low melting point are used to avoid that a temperature of the melted alloys or metals which have a too high melting point is so high that the properties of the inorganic packaging layer are affected.

Furthermore, the metal can be one of a first alloy, a second alloy, and a third alloy. The first alloy consists of 52% of bismuth, 40% of lead, and 8% of cadmium by mass, and its melting point is 92° C. The second alloy consists of 53% of bismuth, 32% of lead, and 15% of tin by mass, and its melting point is 96° C. The third alloy consists of 50% of bismuth, 27% of lead, 13% of tin, and 10% of cadmium by mass, and its melting point is 70° C.

Further, the enhancing sealing structure 140 is formed by solidification of a molten liquid metal or liquid alloy. The molten liquid metal or liquid alloy due to good fluidity can be well filled into the groove or the through hole in the inorganic packaging layer or be formed at the outer edge of the inorganic packaging layer, and cooperates with the inorganic packaging layer to form a dense packaging structure, thereby improving considerably the reliability of the thin film packaging structure 100 and the service life of the OLED device 200.

In one of the embodiments, the afore-described thin film packaging structure 100 further includes a third inorganic packaging layer 150. The third inorganic packaging layer 150 is disposed between the OLED layer 220 and the first inorganic packaging layer 110. Moreover, the third inorganic packaging layer 150 is overlaid on the OLED layer 220, and the first inorganic packaging layer 110 is overlaid on the third inorganic packaging layer 150.

Specifically, the first inorganic packaging layer 110 and the second inorganic packaging layer 130 are silicon nitride thin films. The third inorganic packaging layer 150 is a silicon dioxide thin film or an aluminum oxide thin film. The third inorganic packaging layer 150 has a thinner deposition thickness and better moisture and oxygen barrier properties. Therefore, when the first inorganic packaging layer 110 and the second inorganic packaging layer 130 are silicon nitride thin films, the afore-described third inorganic packaging layer 150 is disposed in turn, which can greatly improve moisture and oxygen barrier properties of the inorganic packaging layer.

Specifically, an edge of the first inorganic packaging layer 110 is disposed on the substrate 210 of the OLED device 200.

Further, in this embodiment, the organic packaging layer 120 is an acrylate thin film. It can be understood that the material of the organic packaging layer 120 is not limited thereto.

Specifically, the first inorganic packaging layer 110 has a thickness of 1 μm to 1.5 μm, the second inorganic packaging layer 130 has a thickness of 1 μm to 1.5 μm, and the third inorganic packaging layer 150 has a thickness of 25 nm to 35 nm.

More specifically, the first inorganic packaging layer 110 has a thickness of 1.2 μm, the second inorganic packaging layer 130 has a thickness of 1.2 μm, and the third inorganic packaging layer 150 has a thickness of 30 nm.

Accordingly, the present disclosure further provides a thin film packaging method for manufacturing the afore-described thin film packaging structure 100 according to an embodiment.

FIG. 3 is a flow chart of the method according to an embodiment of the present disclosure. It should be understood that though the steps in the flowchart of FIG. 3 are sequentially illustrated as indicated by arrows, these steps are not necessarily performed in an order indicated by the arrows. The performance of these steps does not have any sequential limitation such that these steps can be performed in another sequence, unless it is illustrated explicitly in the disclosure. Moreover, at least a part of steps of FIG. 3 can include multiple sub-steps or multiple stages which can be performed at different times rather have to be accomplished at the same time, and can be performed in turn or alternately with at least a part of the other steps or the sub-steps or stages of the other steps, rather have to be performed sequentially.

Specifically, the method includes the steps S302 to S308 below.

In step S302, a first inorganic packaging layer 110 is formed.

Further, in one of the embodiments, the step S1 includes the following step(s): first, overlaying a third inorganic packaging layer 150 on an OLED layer 220 of an OLED device 200 to be packaged, then overlaying the first inorganic packaging layer 110 on the third inorganic packaging layer 150. Specifically, the third inorganic packaging layer 150 is overlaid on the OLED layer 220 of the OLED device 200 which is to be packaged, and an edge of an substrate 210 is exposed, so as to make the first inorganic packaging layer 110 to be formed on the exposed substrate 210 and clad an edge of the third inorganic packaging layer 150.

Specifically, both the first inorganic packaging layer 110 and the third inorganic packaging layer 150 can be formed by chemical vapor deposition.

Specifically, the first inorganic packaging layer 110 is a silicon nitride thin film, and the third inorganic packaging layer 150 is a silicon dioxide thin film or an aluminum oxide thin film.

In step S304, an organic packaging layer 120 is formed on the first inorganic packaging layer 110.

Specifically, the organic packaging layer 120 can be formed by using inkjet printing. Specifically, the organic packaging layer 120 is an acrylate thin film.

In step S306, a second inorganic packaging layer 130 is formed on the organic packaging layer 120.

Specifically, the second inorganic packaging layer 130 can be formed by the chemical vapor deposition. Specifically, the second inorganic packaging layer 130 is a silicon nitride thin film.

In step S308, an enhancing sealing structure 140 is formed surrounding the organic packaging layer 120.

Specifically, as illustrated in FIG. 4, the step S308 can include the following step(s):

In S308A, a groove or through hole surrounding the organic packaging layer 120 is provided in the inorganic packaging layer, a liquid metal or liquid alloy is filled into the groove or through hole, and the enhancing sealing structure 140 is formed by solidifying the liquid metal or liquid alloy.

It can be understood that the step S308 can further include the following step(s):

In S308B, the enhancing sealing structure 140 is disposed surrounding the organic packaging layer 120 directly at an outer edge of the inorganic packaging layer.

The thin film packaging method is easy to operate, and the formed thin film packaging structure 100 has good packaging reliability.

Continuing to refer to FIG. 1 or 2, the present disclosure further provides a display panel 10 according to an embodiment, which includes an OLED device 200 and the afore-described thin film packaging structure 100. The OLED device 200 includes a substrate 210 and an OLED layer 220 disposed on the substrate 210, and a first inorganic packaging layer 110 is overlaid on the OLED layer 220 of the OLED device 200.

Specifically, the OLED layer refers to an organic light-emitting layer. Specifically, the substrate is a thin film transistor (TFT) array substrate.

The display panel 10 uses the afore-described thin film packaging structure 100, and has improved package reliability and an improved service life.

All of the technical features in the embodiments described above can be employed in arbitrary combinations. For purpose of simplifying the description, not all arbitrary combinations of the technical features in the embodiments illustrated above are described. However, as long as such combinations of the technical features are not contradictory, they should be considered as within the scope of the disclosure in the specification.

The above embodiments are merely illustrative of several implementations of the disclosure, and the description thereof is more specific and detailed, but should not be deemed as limitations to the scope of the present disclosure. It should be noted that variations and improvements will become apparent to those skilled in the art to which the present disclosure pertains without departing from its scope. Therefore, the scope of the present disclosure is defined by the appended claims.

1. A thin film packaging structure comprising:
at least two laminated inorganic packaging layers;
an organic packaging layer disposed between the two adjacent inorganic packaging layers; and
an enhancing sealing structure disposed surrounding the organic packaging layer.

2. The thin film packaging structure of claim 1, wherein the enhancing sealing structure is disposed surrounding a peripheral the organic packaging layer.

3. The thin film packaging structure of claim 2, wherein the enhancing sealing structure is disposed in the inorganic packaging layer and proximate to an outer edge of the inorganic packaging layer.

4. The thin film packaging structure of claim 3, wherein peripheral regions of two adjacent inorganic packaging layers are attached to each other to collectively clad the organic packaging layer, and the enhancing sealing structure is disposed within the peripheral region and penetrates at least one of the two adjacent inorganic packaging layers.

5. The thin film packaging structure of claim 2, wherein the enhancing sealing structure is disposed surrounding an outer edge of the inorganic packaging layer.

6. The thin film packaging structure of claim 1, wherein the enhancing sealing structure has a thickness greater than a thickness of the organic packaging layer.

7. The thin film packaging structure of claim 1, wherein the enhancing sealing structure is located in the inorganic packaging layer, and located above or under the organic packaging layer.

8. The thin film packaging structure of claim 1, wherein a material of the enhancing sealing structure is an alloy or a metal.

9. A thin film packaging method, comprising:
forming a first inorganic packaging layer;
forming an organic packaging layer overlaying the first inorganic packaging layer;
forming a second inorganic packaging layer overlaying the organic packaging layer; and
forming an enhancing sealing structure surrounding the organic packaging layer.

10. The method of claim 9, wherein the forming the enhancing sealing structure surrounding the organic packaging layer comprises:
defining a groove or a through hole surrounding the organic packaging layer in the first inorganic packaging layer and in the second inorganic packaging layer, filling a liquid metal or a liquid alloy into the groove or the through hole, and forming the enhancing sealing structure by solidifying the liquid metal or the liquid alloy.

11. The method of claim 9, wherein the forming the enhancing sealing structure surrounding the organic packaging layer comprises:
disposing the enhancing sealing structure surrounding the organic packaging layer directly at an outer edge of the first inorganic packaging layer and the second inorganic packaging layer.

12. A display panel, comprising a thin film packaging structure, wherein the thin film packaging structure thereof comprises:
at least two laminated inorganic packaging layers;
an organic packaging layer disposed between the two adjacent inorganic packaging layers; and
an enhancing sealing structure disposed surrounding the organic packaging layer.

13. The display panel of claim 12, wherein the enhancing sealing structure is disposed surrounding a peripheral of the organic packaging layer.

14. The display panel of claim 13, wherein the enhancing sealing structure is disposed in the inorganic packaging layer and proximate to an outer edge of the inorganic packaging layer.

15. The thin film packaging structure of claim 14, wherein peripheral regions of two adjacent inorganic packaging layers are attached to each other to collectively clad the organic packaging layer, and the enhancing sealing structure is disposed within the peripheral region and penetrates at least one of the two adjacent inorganic packaging layers.

16. The display panel of claim 12, wherein the enhancing sealing structure is disposed surrounding an outer edge of the inorganic packaging layer.

17. The display panel of claim 12, wherein the enhancing sealing structure has a thickness greater than a thickness of the organic packaging layer.

18. The display panel of claim 12, wherein the enhancing sealing structure is located in the inorganic packaging layer, and located above or under the organic packaging layer.

19. The display panel of claim 12, wherein a material of the enhancing sealing structure is an alloy or a metal.
